(19) United States
(12) Patent Application Publication
(10) Pub. No.: US 2007/0238264 A1
(43) Pub. Date: Oct. 11, 2007

(54) Method and apparatus for supporting wafer

(76) Inventor: Kazuma Sekiya, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/783,695

(22) Filed: Apr. 11, 2007

(30) Foreign Application Priority Data
Apr. 11, 2006 (JP) 2006-108609

(51) Int. Cl. H01L 21/00

(52) U.S. Cl. 438/460; 438/464

(57) ABSTRACT

To support a wafer integrally with a ring frame via an adhesive tape without damaging the wafer, and preventing a bubble from entering between the wafer and the adhesive tape, a surface side of the wafer is held on a chuck table; a central portion of an adhesive surface of the adhesive tape adhered with the ring frame on a peripheral edge is aligned with a position opposed to the wafer; then a balloon arranged in a position opposed to a central portion of a non-adhesive surface of the adhesive tape is expanded; and then the balloon presses the adhesive tape to adhere the adhesive surface of the adhesive tape on the back of the wafer. The balloon gradually presses the adhesive tape toward a periphery side to adhere the adhesive tape on the wafer, and accordingly a bubble may not enter between the adhesive tape and the wafer.

### BACKGROUND OF THE INVENTION

1. Field of the Invention

The present invention relates to a method of supporting wafer integrally with a ring-shaped frame via an adhesive tape, and an apparatus preferable for carrying out the method.

2. Related Art

A wafer having devices such as IC or LSI formed thereon is made into a desired thickness by back grinding, then divided into chips for individual devices by dicing. During dicing operation, the wafer is adhered on an adhesive tape, and a ring-shaped frame is adhered on a peripheral edge of the adhesive tape, resulting in a condition that the wafer is supported integrally with the ring-shaped frame via the adhesive tape. When the adhesive tape is adhered on the wafer and the frame before dicing, for example, a taping machine described in JP-A-10-209251 is used.

### SUMMARY OF THE INVENTION

However, when thickness of a wafer is reduced to 100 μm or less, 50 μm or less, or the like, the wafer is not easily handled, and when the wafer is removed from a holding table for holding the wafer in a processing apparatus in which the wafer is thinned, then the adhesive tape is adhered on the wafer and the ring-shaped frame, the wafer may be damaged.

In the case of a particularly thin wafer, a bubble may enter between the adhesive tape and the wafer, causing a portion being not adhered. In this case, it is likely that when the wafer is cut into individual chips, cutting depth becomes non-uniform and thus chipping occurs in a chip, or a chip is scattered and damaged during dicing.

Thus, a difficulty to be solved by an embodiment of the invention is that when the wafer is adhered with an adhesive tape and supported integrally with a ring frame, the wafer is adhered on the adhesive tape without damaging the wafer, and a bubble is prevented from entering between the wafer and the adhesive tape.

A first aspect of the invention relates to a method of supporting a wafer, in which a back of the wafer is adhered with an adhesive tape, and the wafer is supported by a ring frame integrally with the ring frame via the adhesive tape, the method including a wafer holding step of holding a surface side of the wafer on a chuck table, an alignment step of aligning a central portion of an adhesive surface of the adhesive tape adhered with the ring frame on a peripheral edge with a position opposed to the wafer held on the chuck table, and an adhesive tape adhesion step of supplying air into a balloon arranged in a position opposed to a central portion of a non-adhesive surface of the adhesive tape to expand the balloon, so that the balloon presses the adhesive tape to adhere the adhesive surface of the adhesive tape on the back of the wafer.

The chuck table may further act as a chuck table of a grinding device for grinding the back of the wafer. Moreover, in the case of a wafer in which a concave portion is formed on a back of a device region having devices formed therein, and a ring-shaped reinforcement portion is formed at a periphery side of the concave portion, the chuck table may further act as a chuck table of a processing device for removing the ring-shaped reinforcement portion.

A second aspect of the invention relates to an apparatus for supporting a wafer, in which a back of the wafer is adhered with an adhesive tape, and the wafer is supported by a ring frame integrally with the ring frame via the adhesive tape, the apparatus including at least a chuck table for holding the wafer, and a frame supporting unit for aligning an adhesive surface of the adhesive tape adhered on a peripheral edge of the ring frame with a position opposed to the wafer held on the chuck table, and adhering the adhesive tape on the wafer, the frame supporting unit including at least a ring frame holding section for holding the ring frame, a balloon arranged in a position opposed to a central portion of a non-adhesive surface of the adhesive tape, and an air supply source for supplying air into the balloon to expand the balloon.

The chuck table may further act as a chuck table of a grinding device for grinding the back of the wafer. Moreover, in the case of a wafer in which a concave portion is formed on a back of a device region having devices formed therein, and a ring-shaped reinforcement portion is formed at a periphery side of the concave portion, the chuck table may further act as a chuck table of a processing device for removing the ring-shaped reinforcement portion.

According to the aspects of the invention, since the adhesive tape pressed by the balloon is gradually adhered on the wafer from the central portion to the periphery side with expansion of the balloon, the wafer can be supported by the ring frame via the adhesive tape without causing entering of a bubble between the adhesive tape and the wafer, and without damaging the wafer. When the chuck table further acts as the chuck table of the grinding device or processing device, the adhesive tape can be adhered on the wafer without removing a thinned wafer from the chuck table.

### BRIEF DESCRIPTION OF THE DRAWINGS

FIG. 1 is a perspective view showing an example of a wafer supporting apparatus and a processing device;

FIG. 2 is a perspective view showing a ring frame adhered with an adhesive tape;

FIG. 3 is a perspective view showing a condition that the wafer is supported on a chuck table;

FIG. 4 is an explanatory view showing a condition of grinding the wafer;

FIG. 5 is a perspective view showing a condition that a ground wafer is held on the chuck table;

FIG. 6 is a perspective view showing a condition that the ring frame adhered with the adhesive tape is carried to a position above the wafer;

FIG. 7 is a front view showing a condition that an adhesive surface of the adhesive tape is opposed to the wafer;

FIG. 8 is a perspective view showing a condition that the adhesive tape is adhered on the wafer;

FIG. 9 is a front view showing the condition that the adhesive tape is adhered on the wafer; and

FIG. 10 is a perspective view showing a wafer being adhered on the adhesive tape and supported integrally with the ring frame.

### DETAILED DESCRIPTION OF THE PREFERRED EMBODIMENTS

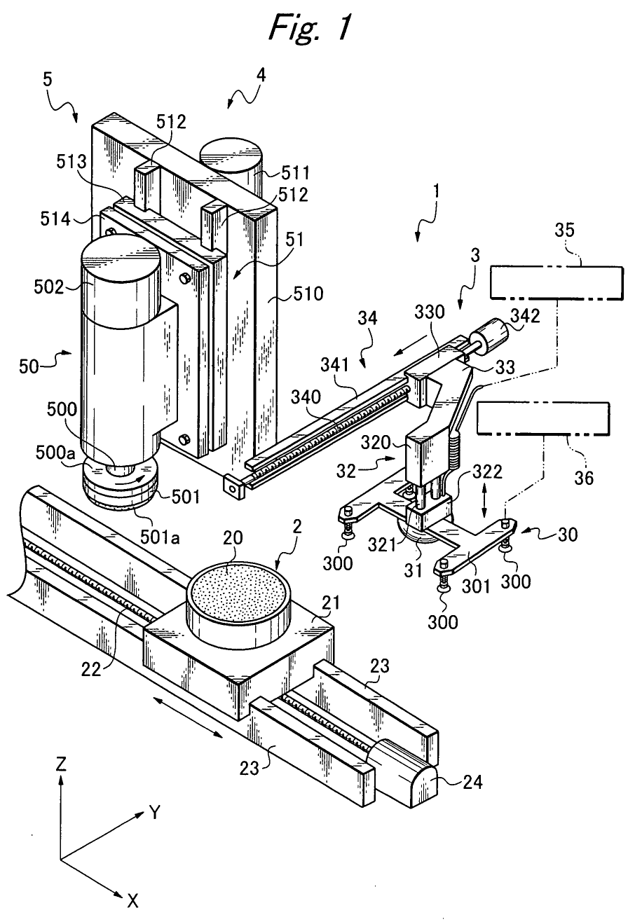

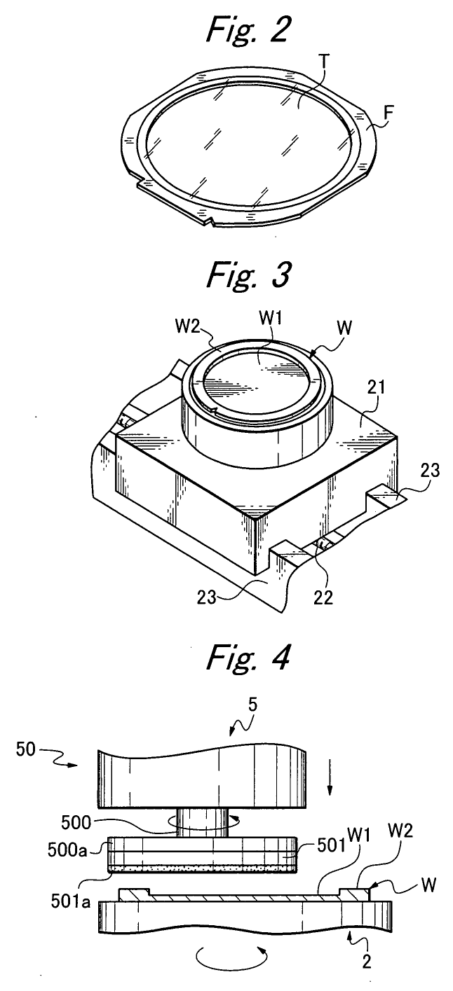

A wafer supporting device 1 shown in FIG. 1 has a chuck table 2 for holding a wafer, and a frame supporting unit 3 for supporting a ring frame F adhered with an adhesive tape T so as to close an opening of the ring frame F as shown in FIG. 2.

The chuck table 2 in an example of FIG. 1 further acts as a chuck table of a processing device 4, and has a holding surface 20 for holding the wafer W. The chuck table 2 is supported by a movable base 21, and the movable base 21 has an inside nut screwed on a ball screw 22 arranged in an X-axis direction, and a lower portion slidably contacted to a pair of guide rails 23 arranged in the X-axis direction. In a configuration of the chuck table, the ball screw 22 is connected with a pulse motor 24 at one end, and as the ball screw 22 is driven to be rotated by the pulse motor 24, the movable base 21 is guided to be moved in the X-axis direction by the guide rail 23, and the chuck table 2 supported by the movable base 21 is also moved in the X-axis direction.

The frame supporting unit 3 has a ring frame holding section 30 including a plurality of adsorption pads 300 being communicated with a vacuum source and adsorbing the ring frame F, and an adsorption pad holding section 301 for supporting the adsorption pads 300; a balloon 31 fixed to a bottom of the adsorption pad holding section 301 to be expanded by air; an up-and-down drive section 32 for moving up and down the ring frame holding section 30; an arm section 33 having the up-and-down drive section 32 at an end; a feed section 34 for moving the arm section 33 in a Y-axis direction; an air supply section 35 for supplying air into the balloon 31 to expand the balloon; and a vacuum source 36 that allows the adsorption pad 300 to exert suction force.

The up-and-down drive section 32 includes an air cylinder 320; a piston rod 321 to be moved up and down with drive by the air cylinder 320; and an up-and-down section 322 fixed to a lower end of the piston rod 321 and moving up and down with the piston rod 321. The adsorption pad holding section 301 is fixed to the up-and-down section 322, and moves up and down with up-and-down movement of the up-and-down section 322.

The air cylinder 320 is arranged in the end of the arm section 33, and a nut within a base 330 of the arm section 33 is screwed on a ball screw 340 arranged in the Y-axis direction. A side face side of the base 330 is slidably contacted to a guide rail 341 arranged in the Y-axis direction. In the configuration, the ball screw 340 is connected with a pulse motor 342 at one end, and as the ball screw 340 is driven to be rotated by the pulse motor 342, the base 330 is guided to be moved in the Y-axis direction by the guide rail 341, and the arm section 33 is also moved in the Y-axis direction.

The processing device 4 has the chuck table 2, and a grinding unit 5. The grinding unit 5 includes a spindle unit 50 including a spindle 500 having a vertical axis, a grinding wheel 501 attached on the spindle 500 via a wheel mount 500a, and a motor 502 for rotating the spindle 500; and a grinding feed unit 51 for moving up and down the spindle unit 50. A grindstone 501a is adhered to a bottom of the grinding wheel 501.

The grinding feed unit 51 includes a not-shown ball screw vertically arranged on a back side of a wall 510; a pulse motor 511 connected to an upper end of the ball screw; a vertically arranged guide rail 512; an up-and-down plate 513 being slidably contacted to the guide rail 512 and having an inside nut screwed on the ball screw; and a connection member 514 being fixed to the up-and-down plate 513 and attached with the spindle unit 50. In a configuration of the grinding feed unit, as the up-and-down plate 513 is driven by the pulse motor 511 and thus moved up and down with being guided by the guide rail 512, the spindle unit 50 also moves up and down.

As shown in FIG. 3, the chuck table 2 holds a surface side of the wafer W (wafer holding step). The shown wafer W is a wafer of a type in which a concave portion W1 is formed on a back of a device region in a surface on which a plurality of devices are formed and in which a convex like ring-shaped reinforcement portion W2 at a periphery side of the concave portion. The processing device 4 has a function of removing the ring-shaped reinforcement portion W2.

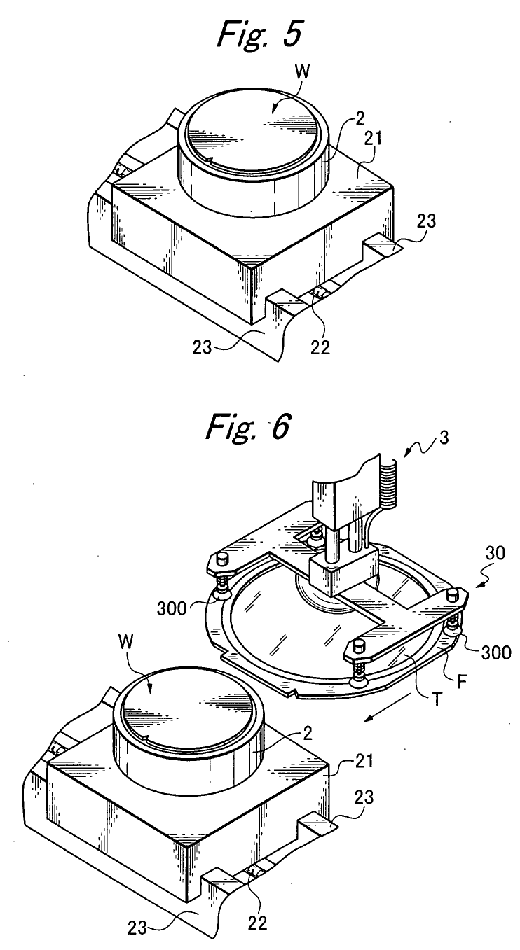

The wafer W is moved to a position directly below the grinding unit 4 with movement in the X-axis direction of the chuck table 2. Then, as shown in FIG. 4, the wafer W is rotated by rotation of the chuck table 2, and the grinding wheel 501 is driven by the grinding feed unit 51 and thus lowered while being rotated, consequently the rotating grindstone 501a is contacted to the ring-shaped reinforcement portion W2 of the wafer W. Then, as shown in FIG. 5, the ring-shaped reinforcement portion W2 is removed, resulting in formation of a flat back of the wafer.

Next, as shown in FIG. 6, the adsorption pad 300 configuring the frame supporting unit 3 is allowed to exert suction force. Then, while the ring frame F adhered on the peripheral edge of the adhesive tape T as shown in FIG. 2 is adsorbed and held, the ring frame holding section 30 is driven to be moved in the Y-axis direction by the feed section 34 shown in FIG. 1. Then, the adhesive tape T adhered on the ring frame F is aligned with a portion directly above the wafer W held by the chuck table 2, so that a central portion of an adhesive surface of the adhesive tape T is made opposed to the wafer W (aligning step). At that time, the balloon 31 is situated in a position facing a central portion of a non-adhesive surface (top) of the adhesive tape T.

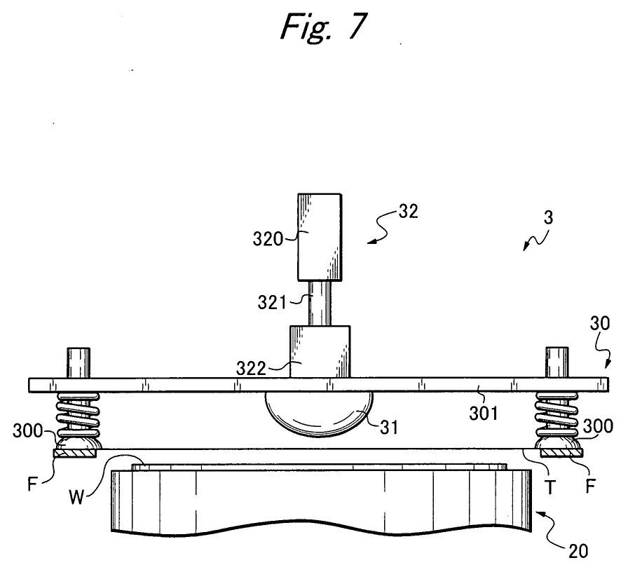

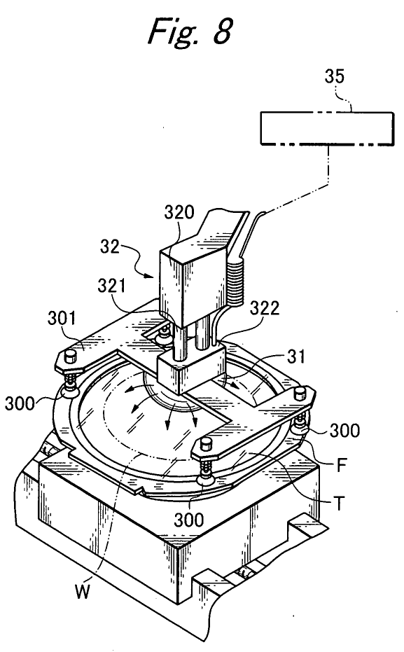

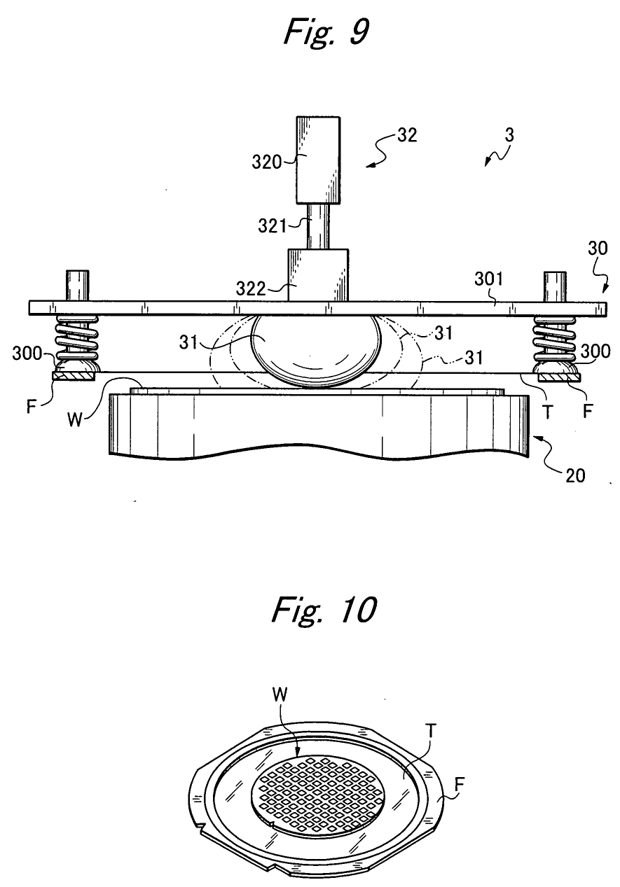

Then, as shown in FIG. 7, the ring frame holding section 30 is lowered, and such lowering is stopped in a condition just before the adhesive tape T is contacted to the wafer W. Next, as shown in FIG. 8 and FIG. 9, air is supplied from an air supply source 35 into the balloon 31 to gradually expand the balloon 31. Thus, the balloon 31 is contacted to the non-adhesive surface of the adhesive tape T, thereby the adhesive tape T is pressed downward so that the adhesive surface (bottom) of the adhesive tape T is adhered on the back of the wafer W. When the balloon 31 is further expanded, a contact portion between the adhesive surface of the adhesive tape T and the back of the wafer W is gradually increased. Accordingly, the adhesive tape T is gradually adhered on the back from a central portion of the back of the wafer W to the periphery, consequently the adhesive tape T is adhered on the whole back of the wafer W. Then, when the wafer W is inverted, a condition that the wafer W is supported integrally with the ring frame F via the adhesive tape T is given as shown in FIG. 10 (adhesive tape adhesion step).

In this way, the balloon 31 gradually presses the adhesive tape T toward the periphery side, thereby the adhesive tape T is adhered on the wafer W. Therefore, a bubble does not enter between the adhesive tape T and the wafer W. Consequently, it is not likely that when the wafer W is cut into individual chips, cutting depth becomes non-uniform and thus chipping occurs in a chip, or a chip is scattered and damaged during dicing.

In the example, description was made on a case that the adhesive tape was adhered after removing the ring-shaped reinforcement portion of the wafer having the back on which the concave portion was formed. However, in the case of a wafer having a back being formed flat, the back of the wafer is ground to be formed into a desired thickness while the wafer is held on the chuck table of the grinding device, and then the wafer held on the chuck table is adhered with the adhesive tape using the frame supporting unit 3.

What is claimed is:

1. A method of supporting a wafer, in which a back of the wafer is adhered with an adhesive tape, and the wafer is supported by a ring frame integrally with the ring frame via the adhesive tape, comprising:
a wafer holding step of holding a surface side of the wafer on a chuck table,
an alignment step of aligning a central portion of an adhesive surface of the adhesive tape adhered with the ring frame on a peripheral edge with a position opposed to the wafer held on the chuck table, and
an adhesive tape adhesion step of supplying air into a balloon arranged in a position opposed to a central portion of a non-adhesive surface of the adhesive tape to expand the balloon, so that the balloon presses the adhesive tape to adhere the adhesive surface of the adhesive tape on the back of the wafer.

2. The method of supporting the wafer according to claim 1, wherein the chuck table further acts as a chuck table of a grinding device for grinding the back of the wafer.

3. The method of supporting the wafer according to claim 1, wherein the wafer has a concave portion formed on a back of a device region having devices formed therein, and a ring-shaped reinforcement portion formed at a periphery side of the concave portion, and
the chuck table further acts as a chuck table of a processing device for removing the ring-shaped reinforcement portion.

4. An apparatus for supporting a wafer, in which a back of the wafer is adhered with an adhesive tape, and the wafer is supported by a ring frame integrally with the ring frame via the adhesive tape, comprising:
at least a chuck table for holding the wafer, and
a frame supporting unit for aligning an adhesive surface of the adhesive tape adhered on a peripheral edge of the ring frame with a position opposed to the wafer held on the chuck table, and adhering the adhesive tape on the wafer,
the frame supporting unit including at least a ring frame holding section for holding the ring frame,
a balloon arranged in a position opposed to a central portion of a non-adhesive surface of the adhesive tape, and
an air supply source for supplying air into the balloon to expand the balloon.

5. The apparatus for supporting the wafer according to claim 4, wherein the chuck table further acts as a chuck table of a grinding device for grinding the back of the wafer.

6. The apparatus for supporting the wafer according to claim 4, wherein the wafer has a concave portion formed on a back of a device region having devices formed therein, and a ring-shaped reinforcement portion formed at a periphery side of the concave portion, and
the chuck table is arranged in a processing device for removing the ring-shaped reinforcement portion.
